(19) United States
(12) Patent Application Publication
(10) Pub. No.: US 2024/0051024 A1
(43) Pub. Date: Feb. 15, 2024

(54) IRRADIATION STRATEGY IN ADDITIVE MANUFACTURING WITH PULSED IRRADIATION

(71) Applicant: Siemens Energy Global GmbH & Co. KG, Munich, Bayem (DE)

(72) Inventors: Timo Heitmann, Berlin (DE); Jan Pascal Bogner, Berlin (DE); Ole Geisen, Berlin (DE)

(73) Assignee: Siemens Energy Global GmbH & Co. KG, Munich, Bayern (DE)

(21) Appl. No.: 18/266,980

(22) PCT Filed: Nov. 24, 2021
(86) PCT No.: PCT/EP2021/082833

§ 371 Date: Jun. 13, 2023

(30) Foreign Application Priority Data
Dec. 22, 2020 (EP) 20216448.9

(51) Int. Cl. B22F 10/366; B33Y 50/02; B22F 10/85

(52) U.S. Cl. CPC B22F 10/366; B33Y 50/02; B22F 10/85

(57) ABSTRACT

A method for powder-bed-based additive manufacturing of a component, includes setting irradiation vectors for a layer to be irradiated for the component, wherein, irradiation vectors are irradiated below a length of 1 mm in a pulsed irradiation operation; and a pulse frequency below 3 kHz and a scan speed below 250 mm/a are selected. A correspondingly manufactured component is produced.

### CROSS REFERENCE TO RELATED APPLICATIONS

This application is the US National Stage of International Application No. PCT/EP2021/082833 filed 24 Nov. 2021, and claims the benefit thereof. The International Application claims the benefit of European Application No. EP20216448 filed 22 Dec. 2020. All of the applications are incorporated by reference herein in their entirety.

### FIELD OF INVENTION

The present invention relates to a method for powder bed-based additive manufacturing of a component or a corresponding (computer implemented) method for providing manufacturing instructions, for example in the course of “computer aided manufacturing”. Furthermore, a correspondingly manufactured component and an associated computer program (product) are specified.

The component is preferably provided for use in the hot gas path of a gas turbine. For example, the component relates to a component to be cooled having a thin-walled or filigree design. Alternatively or additionally, the component can be a component for use in the automotive sector or in the aviation sector.

### BACKGROUND OF INVENTION

High-performance machine components are the subject matter of continuous improvement, in particular to increase their efficiency in use. In heat engines, in particular gas turbines, however, this results in higher and higher usage temperatures, among other things. The metallic materials and the component designs of highly stressable components, such as turbine blades, in particular in the first stages, are continuously improved with respect to their strength, service life, creeping stress carrying capacity, and thermomechanical fatigue.

Generative or additive manufacturing is also increasingly becoming of interest for the series manufacturing of the above-mentioned components, such as turbine blades or burner components, due to its disruptive potential for the industry.

Additive manufacturing methods (AM), also referred to colloquially as 3D printing, comprise, for example, as powder bed methods selective laser melting (SLM) or laser sintering (SLS) or electron beam melting (EBM).

A method for selective laser melting with pulsed radiation is known, for example, from EP 3 022 008 B1.

Additive manufacturing methods have furthermore proven to be particularly advantageous for complex or filigree components, for example labyrinthine structures, cooling structures, and/or light construction structures. In particular, additive manufacturing is advantageous due to a particularly short chain of process steps, since a manufacturing or production step of a component can take place substantially on the basis of a corresponding CAD file and the selection of corresponding manufacturing parameters.

The manufacturing of gas turbine blades by means of the described powder bed-based methods (LPBF, “laser powder bed fusion”) advantageously enables the implementation of novel geometries, concepts, solutions, and/or design, which reduce the manufacturing costs and/or the setup and throughput time, optimize the manufacturing process, and can improve, for example, a thermomechanical design or durability of the components.

Components manufactured in a conventional manner, for example by casting, are significantly inferior to the additive manufacturing route, for example, with respect to their shaping freedom and also in regard to the required throughput time and the high costs connected thereto as well as the manufacturing effort.

This is because high thermal tensions are inherently induced in the component structure by the powder bed process. In particular, irradiation paths or vectors which are dimensioned excessively short result in strong overheating, which in turn results in warping of the structure. Strong warping during the construction process therefore easily results in structural detachments, thermal deformations, or geometric deviations outside a permissible tolerance.

Conventional possible solutions for these problems are to improve the heat dissipation via a construction plate or a construction substrate, since the powder bed is thermally quasi-insulating. Furthermore, the problem could be avoided in that filigree component areas or thin-walled sections, which particularly tend toward thermal warping, are not provided from the outset.

Furthermore, there is the possibility of adapting an irradiation strategy or scanning strategy, in particular lengthening corresponding irradiation vectors, in particular hatching irradiation vectors, by which a cooling time of the correspondingly irradiated powder can be lengthened and the thermal stress can be reduced. However, this possibly implies that thin-walled sections cannot be implemented. Alternatively, the spatially or temporally introduced heat introduction can be reduced by so-called “sky writing”, wherein vectors of a grid-type irradiation are only conceptually lengthened or an energy beam, such as a laser or electron beam, is switched off during the irradiation procedure. The cooling time is thus effectively also lengthened. However, the process efficiency is also impaired by these approaches. In other words, the manufacturing process lasts significantly longer per irradiated layer, which causes costs in the machine occupancy.

### SUMMARY OF INVENTION

It is therefore an object of the present invention to specify means using which the described problems can be solved, in particular means for improved thermal management, in selective irradiation.

This object is achieved by the subject matter of the independent claims. Advantageous embodiments are the subject matter of the dependent claims.

One aspect of the present invention relates to a method for powder bed-based additive manufacturing of a component, comprising defining irradiation vectors for a layer (powder layer) to be selectively irradiated, for example via SLM or EBM, for the component, wherein irradiation vectors having a length below approximately 1 mm are irradiated in a pulsed irradiation mode, wherein a pulse frequency below 3 kHz and a scanning speed below 250 mm/s are selected and/or set. The described parameters are preferably actually applied to individual irradiation vectors and not only to the respective layer to be irradiated as a whole in this case.

A heat introduction into the powder material can advantageously be tailored or adapted by the described means during the production of the component, so that sufficient time is still provided for cooling individual melt pools, which originate from the selective irradiation of the mentioned irradiation vectors. This more or less results in reproducible structure results for the corresponding component layers and in the avoidance of excessive thermal warping and/or tendency toward cracking.

In one embodiment, the irradiation vectors are hatching irradiation vectors. Vectors of this type relate to the main portion of the surfaces to be irradiated of a respective component layer, the solidification of which then possibly only still needs to be completed by so-called contour irradiation (contour irradiation vectors).

In one embodiment, irradiation vectors between 1 mm and 2 mm length are also irradiated in a pulsed irradiation mode, wherein differently a pulse frequency above 3 kHz and a scanning speed above 250 mm/s are selected, however. This embodiment also advantageously permits the advantages according to the invention to be implemented, since excessive heat introduction can also result in a poor structure result (see above) in this range. In particular, higher scanning speeds, namely >250 mm/s, can be used for a powder area to be irradiated accordingly, and this can be done possibly at equal hatching distance. This still enables—in comparison to the lower-frequency and more slowly scanned irradiation—an increase of the productivity with lower energy supply and accordingly reduced overheating (“hot spots”) in the structure of the component.

Furthermore, by way of the mentioned embodiment, wherein according to a critical vector length below 1 mm a lower-frequency pulsed mode and/or from or above 1 mm a higher-frequency pulsed mode is selected, irradiation parameters matched ideally to the geometry of individual component sections can be specified, which enables the additive construction of thin-walled structures at all for the first time. Since a continuous irradiation mode is typically selected for component sections less susceptible to overheating, the present invention possibly advantageously combines the typical continuous wave mode with the pulsed irradiation mode for improved component properties.

In one embodiment, a hatching distance of the irradiation vectors is selected in such a way that an overlap of directly adjacent irradiation vectors of corresponding melt pools is between 30% and 50% of a melt pool width. Due to the overlap thus dimensioned, on the one hand, a comprehensive layer irradiation is expediently achieved and, on the other hand, the overlap of the melt pools or the distance of the irradiation vectors is advantageously adapted to the pulsed irradiation mode. This embodiment is advantageous both for irradiation vectors below 1 mm length and also for those in a range between 1 mm and 2 mm length.

In one embodiment, irradiation vectors from or above a length of approximately 2 mm are irradiated in a continuous irradiation mode or continuous wave mode. As for all above-described embodiments, the irradiation expediently takes place selectively either by a laser beam or an electron beam in the course of the additive manufacturing process.

A further aspect of the present invention relates to a component which can be manufactured or is manufactured according to the described method, wherein the component is provided for use in the hot gas path of a turbomachine, in particular a stationary gas turbine, and includes at least one thin-walled section, for example a section which is particularly susceptible to thermal warping.

A further aspect of the present invention relates to a computer-implemented method for providing manufacturing instructions for the additive manufacturing of a component, comprising defining irradiation parameters, in particular setting the described pulse frequency and scanning speed in the pulsed irradiation mode (see above).

In one embodiment, the computer-implemented method is a CAM method (“computer-aided manufacturing”) or a part thereof.

A further aspect of the present invention relates to a computer program or computer program product, comprising commands which, upon the execution of a corresponding program by a computer, a data processing device, or a control device for irradiation in an additive manufacturing facility, cause these means to define and/or set the irradiation parameters as described above.

A CAD file or a computer program product can be provided or comprised, for example, as a (volatile or nonvolatile) memory medium, such as a memory card, a USB stick, a CD-ROM, or DVD, or also in the form of a downloadable file from a server and/or in a network. The provision can furthermore take place, for example, in a wireless communication network by the transfer of a corresponding file having the computer program product. A computer program product can contain program code, machine code or numeric control instructions, such as G code, and/or other executable program instructions in general.

The computer program product can furthermore contain geometry data or construction data in a three-dimensional format or as CAD data or can comprise a program or program code for providing these data.

Embodiments, features, and/or advantages which relate in the present case to the method or methods or the computer program product can furthermore relate to the component itself, and vice versa.

The expression “and/or” used here, when it is used in a series of two or more elements, means that each of the listed elements can be used alone, or any combination of two or more of the listed elements can be used.

Further details of the invention are described hereinafter on the basis of the figures.

### BRIEF DESCRIPTION OF THE DRAWINGS

FIG. 1 shows a schematic illustration of a powder bed-based, additive manufacturing process.

FIG. 2 shows a schematic perspective view of a component area.

FIG. 3 indicates, on the basis of a schematic top view or cross-sectional view of a layer to be irradiated for a component, method steps according to the invention.

FIG. 4 indicates, on the basis of a schematic top view or cross-sectional view of a layer to be irradiated for a component, method steps according to the invention.

### DETAILED DESCRIPTION OF INVENTION

In the exemplary embodiments and figures, identical or identically acting elements can each be provided with identical reference signs. The elements shown and their size relationships to one another are fundamentally not to be viewed as to scale, rather individual elements can be shown dimensioned exaggeratedly thick or large for better illustration capability and/or for better understanding.

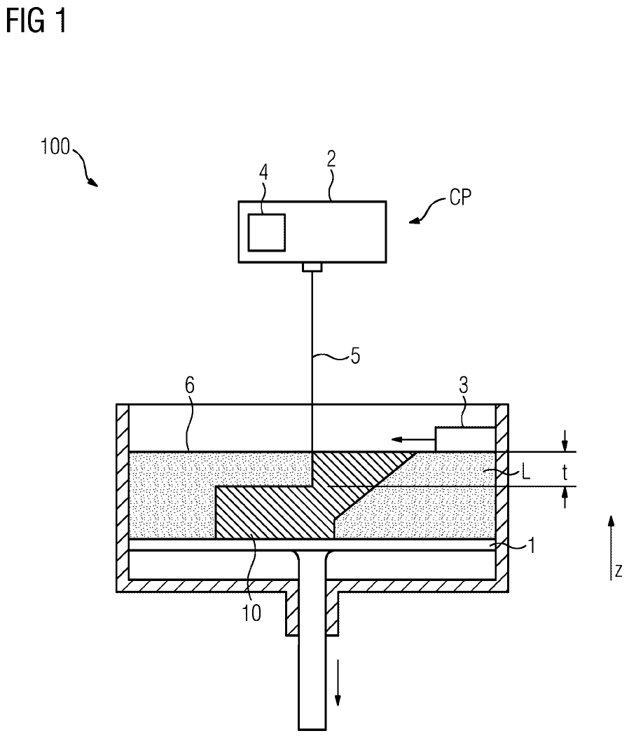

FIG. 1 shows an additive manufacturing facility 100. The manufacturing facility 100 is preferably designed as an LPBF facility and for the additive construction of components or component parts from a powder bed. The facility 100 can especially also relate to a facility for electron-beam melting.

Accordingly, the facility includes a construction platform 1. A component 10 to be additively manufactured is manufactured in layers on the construction platform 1. The powder bed is formed by a powder 6, which can be distributed in layers on the construction platform 1 by a coating device 3.

After the application of each powder layer L—typically having a preset layer thickness t—according to the specified geometry of the component 10, areas of the layer L are selectively melted using an energy beam 5, for example a laser or electron beam, by an irradiation device 2 and subsequently solidified.

After each layer L, the construction platform 1 is preferably lowered by an amount corresponding to the layer thickness L (cf. arrow directed downward in FIG. 1). The thickness t is typically only between 20 μm and 80 μm, preferably 40 μm, so that the entire process can easily comprise an irradiation of tens of thousands of layers.

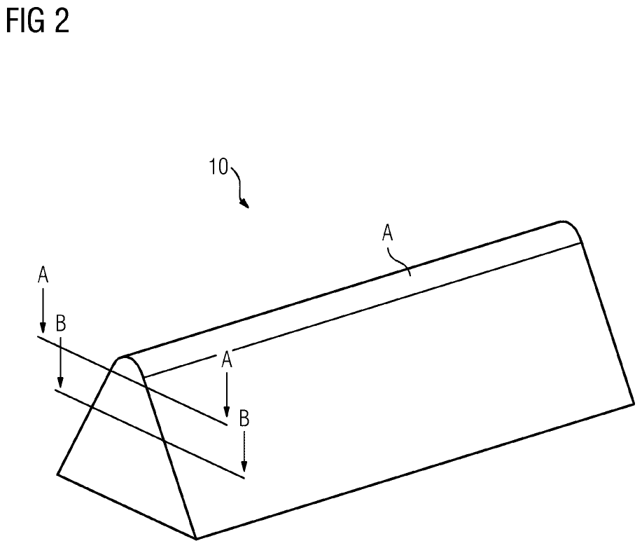

Furthermore, high temperature gradients, for example, of 10⁶ K/s or more, can occur due to the energy introduction, which only acts very locally. The tension state of the component is obviously accordingly large during the construction and also thereafter, which significantly complicates the additive manufacturing processes. Such tension states are all the more critical the more filigree or thin-walled a component area is to be made (cf. FIG. 2 further below), since the tension can then result in strong geometric warping, tendency toward cracking, or even the destruction of the component.

The geometry of the component is typically defined by a CAD file (“computer aided design”). After such a file is read into the manufacturing facility 100, the process then initially requires defining a suitable irradiation strategy, for example, by means of CAM, by which the component geometry is also divided into the individual layers. The irradiation strategy typically comprises defining a large number of irradiation or construction parameters, as further described here.

It is obvious that the selection of a preferred irradiation strategy, comprising defining essential irradiation parameters for the additive manufacturing process of the component, already bears the basic concept according to the invention and with a simple execution of a corresponding irradiation procedure, undoubtedly equips the component with advantageous structural properties. In other words, the advantageous technical properties are already applied to the component by defining corresponding irradiation parameters. Accordingly, a computer program, computer program product CP or a data carrier comprising such a computer program is part of the present invention.

The component 10 can be a component of a turbomachine, for example a component for the hot gas path of a gas turbine. In particular, the component can designate a rotor blade or guide blade, a ring segment, a burner part or a burner tip, a frame, a shield, a heat shield, a nozzle, a seal, a filter, an orifice or lance, a resonator, a plunger, or an agitator, or a corresponding transition, insert, or a corresponding retrofit part.

FIG. 2 schematically shows a component area, comprising a particularly filigree section A, i.e., advantageously a part of the component which is made very thin or filigree in comparison to other component sections. As indicated, such sections A, independently of whether they actually represent a tip of the component or a lateral wall, strongly tend toward mechanical warping and/or cracking. Such warping is not shown in FIG. 2 for the sake of simplicity.

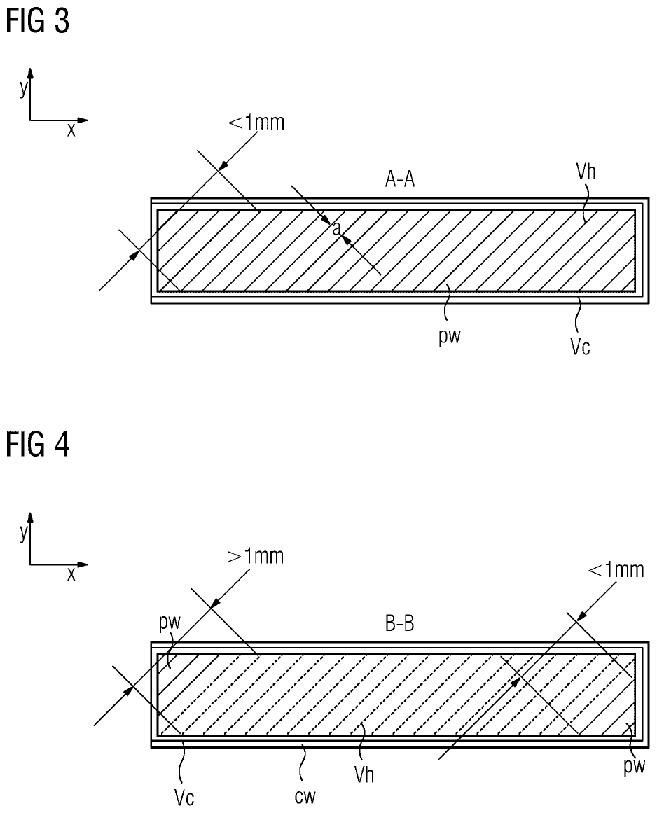

FIG. 3 shows a section or a top view of a layer L along line A-A, as indicated in FIG. 2. In accordance with the relatively small geometrical extension of the layer or the component structure, as shown in FIG. 3, the additive construction thereof in particular requires defining relatively short irradiation vectors, in particular hatching irradiation vectors Vh. In the scope of such construction processes, it is not always possible to perform alignment of the irradiation vectors in consideration of the component geometry layer by layer, so that the vector alignment is partially already defined otherwise or is no longer variable.

Furthermore, contour irradiation vectors Vc are shown in the sectional view of FIG. 3, which border the hatching irradiation vectors Vh, for example to solidify a border area having more reliable structural quality.

The present invention now proposes a method for powder bed-based additive manufacturing of the component 10, according to which irradiation vectors for a corresponding layer L to be irradiated are defined and/or irradiated in such a way that irradiation vectors below a length of 1 mm are irradiated in a pulsed irradiation mode pw, and wherein a pulse frequency below 3 kHz and a scanning speed below 250 mm/s are selected. As described above, the undue thermal warping or tension states may thus be reduced to an amount which ensures sufficient structural quality and adequate dimensional accuracy of the component. The mentioned irradiation vectors are preferably hatching irradiation vectors Vh.

Furthermore, a hatching distance a of the irradiation vectors Vh is shown in FIG. 3, which is selected in such a way that an overlap of directly adjacent irradiation vectors of corresponding melt pools is between 30% and 50%.

FIG. 4 shows a section or a top view of a layer L along line B-B, as indicated in FIG. 2.

In contrast to the illustration of FIG. 3, such a thin-walled or filigree area is not sketched in this sectional view, so that corresponding hatching irradiation vectors Vh—in comparison to the illustration of FIG. 3—can be dimensioned somewhat longer without thermally overloading the structure to be constructed.

Although the vectors shown in the middle of the layer can also be produced using a continuous irradiation mode, it is to be indicated in FIG. 4 that irradiation vectors Vh (cf. borders left and right) also only have a length between 1 mm and 2 mm, for example, and are therefore preferably irradiated in a pulsed irradiation mode pw, wherein a pulse frequency f above 3 kHz and a scanning speed v above 250 mm/s are preferably selected here.

If a (defined) length of the irradiation vectors exceeds, for example, a value of approximately 2 mm, it is possible to make use of a continuous irradiation mode cw, in order to carry out the additive construction process more efficiently with respect to time, for example.

The abovementioned threshold values of 1 mm or 2 mm for the length of corresponding irradiation vectors, which can moreover also relate to the contour irradiation vectors Vc, can be particularly advantageous, since melt pool widths in the described context are expediently between 200 μm and 500 μm, and the powder material possibly does not completely solidify due to the irradiation of a given vector before the closest (adjacent) vector is exposed or irradiated.

The described means advantageously allow, in particular by the matching of scanning speed, pulse parameters, and the mentioned melt pool overlap or the hatching distance, discrete cooling of the individual melt lenses or melt beads to be enabled, and/or the energy introduction by the melting beam to be optimized. In particular sections A, as illustrated on the basis of FIG. 2, are thus reliably protected from overheating.

1. A method for powder bed-based additive manufacturing of a component, comprising:
defining irradiation vectors for a layer to be irradiated for the component,
irradiating the irradiation vectors below a length of 1 mm in a pulsed irradiation mode,
wherein a pulse frequency below 3 kHz and a scanning speed below 250 mm/s are selected.

2. The method as claimed in claim 1,
wherein the irradiation vectors are hatching irradiation vectors.

3. The method as claimed in claim 1, further comprising:
irradiating the irradiation vectors between 1 mm and 2 mm length are also irradiated in a pulsed irradiation mode,
wherein a pulse frequency above 3 kHz and a scanning speed (v) above 250 mm/s are selected.

4. The method as claimed in claim 1,
wherein a hatching distance of the irradiation vectors is selected in such a way that an overlap of directly adjacent irradiation vectors of corresponding melt pools is between 30% and 50%.

5. The method as claimed in claim 1, further comprising:
irradiating the irradiation vectors from a length of approximately 2 mm in a continuous irradiation mode.

6. A computer-implemented method for providing manufacturing instructions for the additive manufacturing of a component, comprising
defining irradiation parameters according to the method as claimed in claim 1.

7. The method as claimed in claim 6,
which is a computer-aided-manufacturing (CAW method.

8. A computer program product stored on a tangible computer readable medium, comprising:
commands which, upon execution of a corresponding program by a computer or a controller of irradiation in an additive manufacturing facility, cause it to implement the method as claimed in claim 1.
